(19) United States
(12) Patent Application Publication
(10) Pub. No.: US 2024/0222175 A1
(43) Pub. Date: Jul. 4, 2024

(54) GRIPPER MODULE FOR GRIPPING A CARRIER, SUBSTRATE TRANSFER APPARATUS INCLUDING A GRIPPER MODULE, AND METHOD OF GRIPPING A CARRIER USING A GRIPPER MODULE

(71) Applicant: SEMES CO., LTD., Cheonan-si, Chungcheongnam-do (KR)

(72) Inventors: Jaehyun LEE, Suwon-si (KR); Hyukjae SUNG, Cheonan-si (KR); Kitae NOH, Seongnam-si (KR); Jonghyun KIM, Asan-si (KR)

(73) Assignee: SEMES CO., LTD., Cheonan-si, Chungcheongnam-do (KR)

(21) Appl. No.: 18/396,288

(22) Filed: Dec. 26, 2023

(30) Foreign Application Priority Data
Dec. 28, 2022 (KR) 10-2022-0187540

(51) Int. Cl. H01L 21/677; B65G 1/04; H01L 21/687

(52) U.S. Cl. CPC H01L 21/6773; B65G 1/0457; H01L 21/67706; H01L 21/67724; H01L 21/67733; H01L 21/68707; B65G 2201/0297

(57) ABSTRACT

A gripper module may include a base plate having a length in a first direction and a width in a second direction substantially perpendicular to the first direction; a driving part including a power source configured to generate a driving force, and a driving block linearly configured to move in the second direction by the driving force and to extend in the first direction; a gripper transfer part including a transfer block configured to be separated from an end portion of the driving block, to extend in the second direction and to linearly move in the first direction; a link block configured to be coupled to the driving block and the transfer block, and to convert a linear movement of the driving block in the second direction into a uniform accelerated linear movement of the transfer block in the first direction; and a gripper configured to be rotatably coupled to the line block, to move a gripping position and a release position according to the uniform accelerated linear movement of the transfer block, and to grip a carrier in the gripping position.

### CROSS-REFERENCE TO RELATED APPLICATION

This application claims priority to Korean Patent Application No. 10-2022-0187540 filed on Dec. 28, 2022 in the Korean Intellectual Property Office (KIPO), the contents of which are herein incorporated by reference in its entirety.

### BACKGROUND

### 1. Field

Example embodiments of the invention relate to a gripper module for gripping a carrier, a substrate transfer apparatus including a gripper module, and a method of gripping a carrier using a gripper module. More particularly, example embodiments of the invention relate to a gripper module for selectively gripping a carrier receiving a plurality of substrates therein, a substrate transfer apparatus including such gripper module, and a method of gripping a carrier using the gripper module.

### 2. Related Technology

A semiconductor device may be manufactured by repeated performing processes of forming various layers on a substrate and selectively removing such various layers. In general, equipments for manufacturing the semiconductor device may be sequentially disposed in a semiconductor manufacturing line such that the equipments may perform various processes on the semiconductor device.

In the processes for manufacturing the semiconductor device, a plurality of substrates may be received in a carrier, and then the carrier having the substrates therein may be transferred into various equipments and may be transferred from the various equipments.

The carrier may be usually transferred using a transfer device such as an overhead hoist transport (OHT). The transfer device may hold the carrier and may move along a traveling rail extending along the semiconductor manufacturing line on which the equipments are sequentially disposed. In this case, the gripper module of the transfer device may grip the carrier using a flange, and then the gripper module may be accommodated in a vehicle which may move along the traveling rail.

The conventional gripper module may include a gripper coupled to the flange, a motor for driving the gripper and a driving part connecting the motor to the gripper. However, the conventional gripper module may include the driving part consisting of a cam follower, so a cam may be frequently deformed by the friction between the cam and a cam housing. If the shape of cam is deformed, a driving force may not be exactly transmitted from the motor to the gripper so that the gripper module may not stably grip the carrier. Additionally, the gripper module may grip the carrier at a substantially constant speed by the driving part having the cam follower such that the transfer efficiency of the carrier among the equipments may be reduced.

Accordingly, there are needs for a gripper module and an apparatus for transferring a substrate including the gripper module which may efficiently grip and transfer a carrier while preventing a driving part having a cam follower from being worn.

### SUMMARY

It is one object of the invention to provide a gripper module including a bearing capable of improving a speed of gripping operation thereof while preventing a failure of the gripping operation caused by an abrasion.

It is another object of the invention to provide a substrate transfer apparatus including the gripper module having the above configuration.

It is still another object of the invention to provide a method of gripping a carrier using the gripper module having the above configuration.

According to an aspect of the invention, there is provided a gripper module. The gripper module may include a base plate having a length in a first direction and a width in a second direction substantially perpendicular to the first direction; a driving part including a power source configured to generate a driving force, and a driving block linearly configured to move in the second direction by the driving force and to extend in the first direction; a gripper transfer part including a transfer block configured to be separated from an end portion of the driving block, to extend in the second direction and to linearly move in the first direction; a link block configured to be coupled to the driving block and the transfer block, and to convert a linear movement of the driving block in the second direction into a uniform accelerated linear movement of the transfer block in the first direction; and a gripper configured to be rotatably coupled to the line block, to move a gripping position and a release position according to the uniform accelerated linear movement of the transfer block, and to grip a carrier in the gripping position.

According to another aspect of the invention, there is provided a substrate transfer apparatus. The substrate transfer apparatus may include a transfer vehicle configured to grip a carrier including a plurality of substrates and to transfer the carrier; a traveling module configured to be disposed on an upper portion of the transfer vehicle and to transfer the transfer vehicle along a traveling rail connected to manufacturing equipments; and a gripper module configured to be disposed in the transfer vehicle, to grip the carrier and to be fixed in the transfer vehicle. In this case, the gripper module may include a base plate having a length in a first direction and a width in a second direction substantially perpendicular to the first direction; a driving part including a power source configured to generate a driving force, and a driving block linearly configured to move in the second direction by the driving force and to extend in the first direction; a gripper transfer part including a transfer block configured to be separated from an end portion of the driving block, to extend in the second direction and to linearly move in the first direction; a link block configured to be coupled to the driving block and the transfer block, and to convert a linear movement of the driving block in the second direction into a uniform accelerated linear movement of the transfer block in the first direction; and a gripper configured to be rotatably coupled to the line block, to move a gripping position and a release position according to the uniform accelerated linear movement of the transfer block, and to grip a carrier in the gripping position.

According to still another aspect of the invention, there is provided a method of gripping a carrier. The method of gripping a carrier may include downwardly moving a gripper onto a load port of a manufacturing equipment on which the carrier is loaded; linearly moving a driving block in a second direction by using the diving force; transmitting the driving force to a pair of the link blocks rotatably coupled to the driving block by a bearing; transmitting the driving force to a pair of the transfer blocks rotatably coupled to the link blocks by the bearing and controlling the pair of the transfer blocks to close to each other; and moving the gripper to a gripping position according to a movement of the transfer blocks.

According to example embodiments, the first and the second rotational couplers may rotate by the veering such that each of the first and the second rotational couplers may rotate with the uniformly accelerated linear movement. Therefore, the transfer block may move with the uniformly accelerated linear movement so that the gripper coupled to the transfer block may also operate with the uniformly accelerated linear movement. As a result, the efficiency of the gripping operation of the gripper module may be considerably improved. Further, it may be prevented or removed a failure of gripping operation caused by the abrasion between the cam housing and the cam follower due to the structural characteristics of the cam follower.

### BRIEF DESCRIPTION OF THE DRAWINGS

Example embodiments will be more clearly understood from the following detailed description taken in conjunction with the accompanying drawing. The following figures represent non-limiting, example embodiments as described herein.

FIG. 1 is a schematic perspective view illustrating a substrate transfer apparatus in accordance with example embodiments of the invention.

FIG. 2 is a cross-sectional view illustrating the substrate transfer apparatus taken along a line I-I′ in FIG. 1.

FIG. 3 is a perspective view illustrating the gripper module of the substrate transfer apparatus in accordance with example embodiments of the invention.

FIG. 4 is a cross-sectional view illustrating the gripper module shown in FIG. 3 taken along a transfer block.

FIG. 5 is a cross-sectional view illustrating the gripper module shown in FIG. 3 taken along a link block.

FIG. 6 is an enlarged cross-sectional view illustrating a first rotational coupler shown in FIG. 5.

FIG. 7 is a flow chart illustrating a method of gripping a carrier using a substrate transfer apparatus in accordance with example embodiments of the invention.

### DESCRIPTION OF EMBODIMENTS

Various embodiments will be described more fully hereinafter with reference to the accompanying drawings, in which some embodiments are shown. The invention may, however, be embodied in many different forms and should not be construed as limited to the embodiments set forth herein. Rather, these embodiments are provided so that this description will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (for example, rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include a plurality of forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the face through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, it will be described an apparatus for transferring a substrate according to example embodiments with reference to the accompanying drawings.

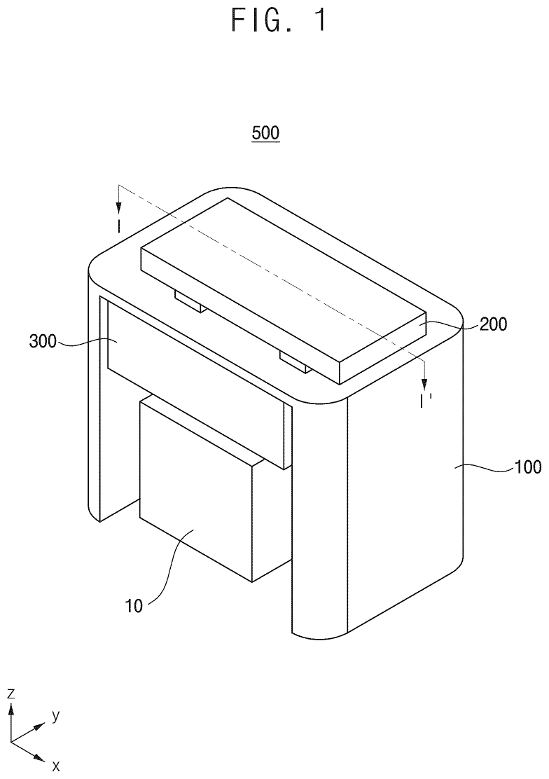

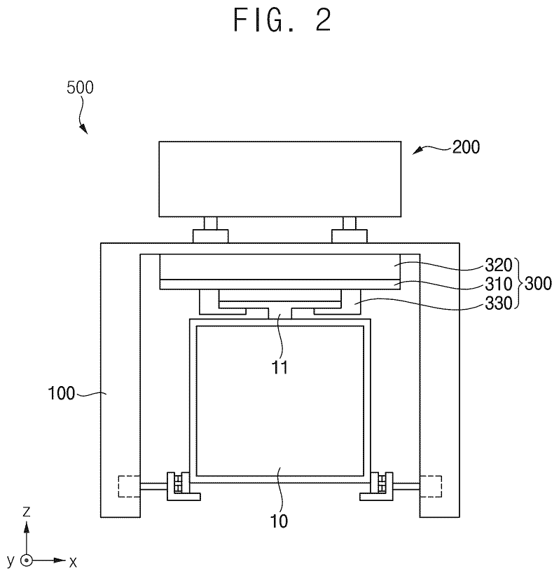

FIG. 1 is a schematic perspective view illustrating a substrate transfer apparatus in accordance with example embodiments of the invention. FIG. 2 is a cross-sectional view illustrating the substrate transfer apparatus taken along a line I-I′ in FIG. 1.

Referring to FIG. 1 and FIG. 2, a substrate transfer apparatus 500 according to example embodiments may include a transfer vehicle 100, a traveling module 200 and a gripper module 300. The transfer vehicle 100 may hold a carrier 10 having a plurality of substrates therein and may transfer the carrier 10 in a desired direction. The traveling module 200 may be disposed over the transfer vehicle 100 and may transfer the transfer vehicle 100 along a traveling rail which may be connected to a plurality of manufacturing equipments. The gripper module 300 may grip the carrier 100 and may be accommodated in the transfer vehicle 100. In this case, the gripper module 300 may be fixed in an inside of the transfer vehicle 100.

In example embodiments, the substrate transfer apparatus 500 may be used to transfer the carrier 10 receiving a plurality of substrates in the processes of manufacturing a semiconductor device. For example, the substrate transfer apparatus 500 may be used to transfer front opening unified pod (FOUP) in which a plurality of semiconductor wafers are received. In this case, the substrate transfer apparatus 500 may include an over hang transport (OHT). The OHT may move along the traveling rail installed on the ceiling of the clean room for manufacturing the semiconductor device and may transfer the substrates into the manufacturing equipments in the manufacturing processes.

As illustrated in FIGS. 1 and 2, the substrate transfer apparatus 500 may include the transfer vehicle 100 configured to hold the carrier 10 and the traveling module 200 configured to moving the transfer vehicle 100 along the traveling rail.

The transfer vehicle 100 may include a housing which may provide an inner space in which the carrier 10 may be accommodated. Hereinafter, a first (x) direction may be referred to as a direction along a length of the housing, a second (y) direction may be referred to as a direction along a width of the housing, and a third (z) direction may be referred to as a direction along a height of the housing. A bottom of the housing and at least a portion of a sidewall of the housing in the second direction (y) may be opened.

The carrier 10 may be loaded into the transfer vehicle 100 through the bottom of the housing and may be unloaded from the transfer vehicle 100 through the bottom of the housing, while the gripper module 300 grips the carrier 10.

The traveling module 200 may be coupled to the transfer vehicle 100 and may be engaged with the traveling rail connected to the manufacturing equipments. The transfer vehicle 100 may be provided from a vehicle source (not illustrated) disposed in the clean room where the manufacturing equipments are installed.

The traveling module 200 may move the transfer vehicle 100 to a load port of the manufacturing equipment where the carrier 10 to be transferred is placed. For example, the traveling module 200 may move the transfer vehicle 100 to the load port according to traveling information set by control algorithm. Then, the gripper module 300 may grip the carrier 10 according to grip information inputted thereto and may move the carrier 10 in the transfer vehicle 100 along an upward direction and a downward direction.

When the carrier 10 is accommodated in the transfer vehicle 100, the traveling module 200 may move the transfer vehicle 100 over the load port of the manufacturing equipment. Then, the carrier 10 may be downwardly moved by the gripper module 300 toward the load port of the manufacturing equipment. When the carrier 10 is located on the load port, the carrier 10 may be released from the gripper module 300.

In some example embodiments, the traveling module 200 may include a control reorganization module and a traveling control module. The control reorganization module may transfer the carrier 10 having the substrates among the manufacturing equipments in accordance with the entire control algorithm of the semiconductor manufacturing line. The traveling control module may run along the traveling rail such that the carrier may be transferred to desired manufacturing equipment.

In example embodiments, the gripper module 300 may be disposed on an inside of the transfer vehicle 100. For example, the gripper module 300 may locate at an inner end portion of the transfer vehicle 100 to grip and hold the carrier 10 including the substrates.

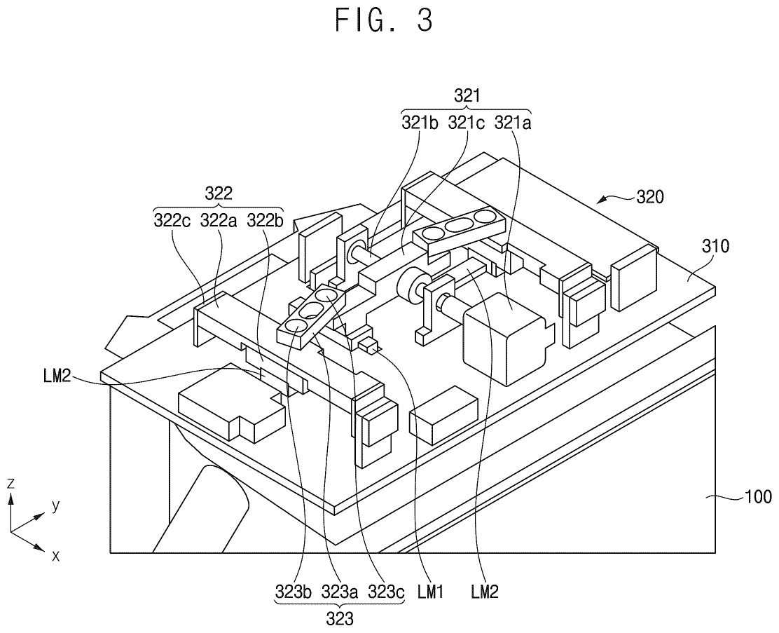

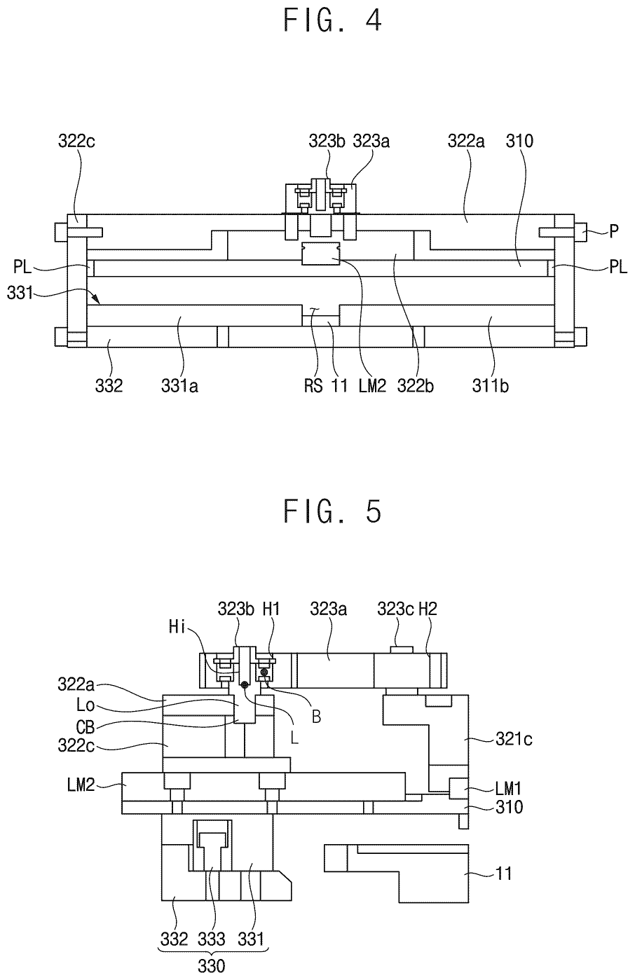

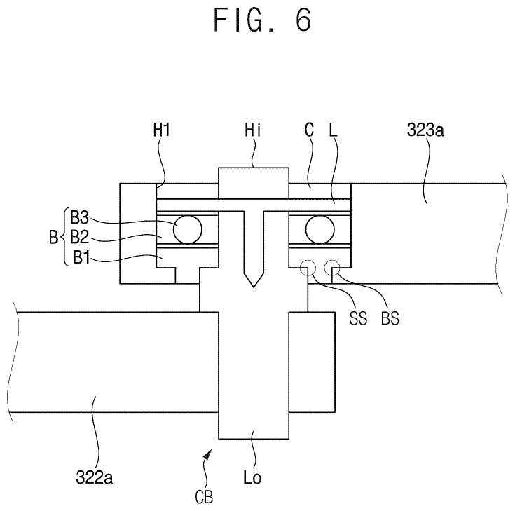

FIG. 3 is a perspective view illustrating the gripper module of the substrate transfer apparatus illustrated in FIG. 1. FIG. 4 is a cross-sectional view illustrating the gripper module shown in FIG. 3 taken along a transfer block. FIG. 5 is a cross-sectional view illustrating the gripper module shown in FIG. 3 taken along a link block. FIG. 6 is an enlarged cross-sectional view illustrating a first rotational coupler shown in FIG. 5.

Referring to FIG. 3 to FIG. 6, the gripper module 300 may include a gripper 330 disposed under a base plate 310 and capable of gripping a flange 11 of the carrier 10. Further, the gripper module 300 may include a gripper controller 320 disposed on the base plate 310 and capable of driving the gripper 330.

The base plate 310 may be provided as a reference line for installing various upper components configured to grip and drive the carrier 10 as well as the gripper controller 320 and for the gripper 330 connected to the gripper controller 320 and disposed under the gripper controller 320.

In example embodiments, the base plate 310 may have a base length in the first direction x and a base width in the second direction y. For example, the base length and the base width of the base plate 310 may be smaller than the length and the width of the transfer vehicle 100, respectively.

The upper components may include various operation and control components such as a lift and a lift driver configured to allow the gripper 330 to descend and ascend together with the gripper controller 320, and a control module configured to control an overall operation of the gripper module 300.

While the substrate transfer apparatus 500 transfers the carrier 10 having the substrates, the gripper 330 may grip and hold the carrier 10. In this case, a sum of loads of the various upper components including the gripper controller 320, the gripper 330 and the carrier 10 may be applied to the base plate 310 as a distributed load. Thus, the base plate 310 may include a plate having sufficient strength and sufficient rigidity so that the base plate 310 may be deformed within an allowable range set relative to the distributed load.

In example embodiments, the gripper controller 320 may include a driving part 321, a gripper transfer part 322, and a link block 323.

The driving part 321 may include a power source 321a, a ball screw 321b and a driving block 321c. The power source 321a may be configured to generate a driving force. The ball screw 321b may linearly move in the second direction y according to the driving force. The driving block 321c may have a central portion fixed to the ball screw 321b. The driving block 321c may linearly move in the second direction y together with the ball screw 321b.

The power source 321a may include a servo motor configured to drive the ball screw 321b. The ball screw 321b may be connected to the power source 321a through a bearing and a coupler. Therefore, a rotational movement generated by the servo motor may be converted into a linear movement in the second direction y through the ball screw 321b.

The driving block 321c may be fixed to the ball screw 321b and may move in the second direction y together with the ball screw 321b. In this case, the driving block 321c may have the central portion fixed to the ball screw 321b, and may have a line structure extending along the first direction x.

In example embodiments, the driving block 321c may have both end portions located symmetrically with respect to the ball screw 321b. Therefore, a pair of link blocks 323 may be coupled to the both end portions of the driving block 321c while being spaced apart from the ball screw 321b by the substantially same distance. In this case, one end portion of the driving block 321c may be coupled to a driving rail LM1 disposed under the one end portion of the driving block 321c to minimize a rolling resistance against the linear movement of the driving block 321c in the second direction y. The remaining end portions except for the end portion that makes contact with the driving rail LM1 may be spaced apart from the base plate 310 without contacting the rail. Therefore, the driving block 321c may linearly move along the driving rail LM1 disposed on only one side of the driving block 321c to minimize a movement resistance during the linear movement.

As described above, the rotational driving force from the power source 321a may be converted into the linear driving force by the driving block 321c, and then transmitted to the gripper transfer part 322 through the link block 323.

The gripper transfer part 322 may include a transfer block 322a, a transfer bracket 322b and a gripper coupling plate 322c. The transfer block 322a may be spaced apart from an end portion of the driving block 321c in the first direction x and may have a substantial line shape. The transfer block 322a may extend in the second direction y and may linearly move in the first direction x. The transfer bracket 322b may be coupled to a lower portion of the transfer block 322a and may transfer the transfer block 322a in the first direction x. The gripper coupling plate 322c may be coupled to both end portions of the transfer block 322a and may extend in the third direction z substantially perpendicular to the first direction x and the second direction y through the base plate 310.

The transfer block 322a may be connected to the gripper 330 disposed under the base plate 310 and may serve as a support body supporting the gripper 330. The transfer block 322a may include a plate which may have sufficient strength and sufficient rigidity to support a load of the gripper 330, and may have a sufficient length to receive a width of the carrier 10 gripped by the gripper 330.

While the driving block 321c may have the substantial line shape extending in the first direction x, the transfer block 322a may have the line-shaped plate extending in the second direction y and being spaced apart from the both end portions of the driving block 321c. Therefore, a pair of transfer blocks 322a may be provided as a pair of line plates arranged symmetrically with respect to the driving block 321c.

In example embodiments, the pair of transfer blocks 322a may be spaced apart from the base plate 310 by a predetermined distance in order to reduce a movement resistance during the transfer operation of the carrier 10. In other words, each of the transfer brackets 322b may be disposed at a central lower portion of the transfer block 322a, and the transfer bracket 322b may be coupled onto a transfer rail LM2 disposed on the base plate 310 and may linearly move in the first direction x by the driving force transmitted from the driving block 321c.

The transfer rail LM2 may be disposed on the base plate 310, the transfer bracket 322b may be coupled on to the transfer rail LM2, and the transfer block 322a may be coupled to the transfer bracket 322b. Accordingly, the transfer block 322a may be spaced apart from the base plate 310 by a predetermined distance, and the transfer block 322a may move in the first direction x together with the transfer bracket 322b.

The transfer bracket 322b may move by the driving power transmitted through the link block 323. The link block 323 may be rotatably coupled to the driving block 321c and the transfer block 322a to convert the linear movement of the driving block 321c in the second direction y into the uniformly accelerated linear movement of the transfer block 322a in the first direction x. Therefore, compared with the conventional gripper module including the cam follower and moving the uniform motion, the operation speed of the gripper module 300 may be greatly enhanced through the uniformly accelerated linear movement of the transfer block 322a.

In example embodiments, the link block 323 may include a body 323a, a first rotational coupler 323b and a second rotational coupler 323c. The body 323a may have a substantial bar shape. The first rotational coupler 323b may pass through a first end portion of the body 323a. The first rotational coupler 323b may include a bearing B1 disposed in a first through hole H1 having a body step BS at a lower portion thereof. The first rotational coupler 323b may fix the body 323a to the transfer block 322a. The second rotational coupler 323c may pass through a second end portion of the body 323a. The second rotational coupler 323c may include a bearing B2 disposed in a second through hole H2 having a body step BS at a lower portion thereof. The second rotational coupler 323c may rotatably fix the driving block 321c to the body 323a.

The body 323a may include a bar-shaped plate which may have sufficient strength to transmit the linear movement of the driving block 321c to the transfer block 322a. Since the body 323a may rotate at an end portion of the driving block 321c and a central portion of the transfer block 322a, the body 323a may be formed of various materials having various shapes, which have sufficient rigid body characteristics to perform the rotational movement.

The first rotational coupler 323b and the second rotational couplers 323c may be coupled to each other and may transmit the uniformly accelerated linear movement to the transfer block 322a. Thus, each of the first and the second rotational couplers 323b and 323c may have various configurations which can transfer the transfer block 322a with the uniformly accelerated linear movement.

In example embodiments, the first and the second rotational couplers 323b and 323c may have the substantially same configuration and may couple the body 323a to the transfer block 322a and the driving block 321c, respectively. Therefore, the first rotational coupler 323b will be described whereas the description of the second rotational coupler 323c will be omitted.

As illustrated in FIG. 5 and FIG. 6, the first rotational coupler 323b may include a first coupling base CB and a fixing part L. The first coupling base CB may include a lower base Lo and an upper base Hi. The lower base Lo may be fixed to the transfer block 322a. The upper base Hi may extend from the lower base Lo through a central portion of the first through hole H1. The upper base Hi may be surrounded by the bearing B. The fixing part L may fill the first through hole H1 and may fix the bearing B to the upper base Hi to separate the bearing B from an outside.

The upper base Hi may include an outer surface having a surface step SS substantially corresponding to the body step BS. A space for receiving the bearing B may be provided over the body step BS and the surface step SS. A hole having a size smaller than that of the first through hole H1 may be disposed between the body step BS and the surface step SS. Such hole may serve a coupling hole to which a turning wheel B1 of the veering B is coupled.

The bearing B may include the turning wheel B1, a retainer B2 and a plurality of rigid body balls B3. The turning wheel B1 may be disposed on both of the body step BS and the surface step SS. The turning wheel B1 may surround the upper base Hi and may rotate relative to the upper base Hi. The retainer B2 may be disposed over the turning wheel B1 and may locate to surround the upper base Hi. The plurality of rigid body balls B3 may be arranged in the retainer B2 by a constant distance. The rigid body balls B3 may rotate along a circumference of the upper base Hi in accordance with the rotation of the body 323a.

When the driving block 321c linearly moves in a direction away from the power source 321a in the second direction y, the body 323a of the link block 323 coupled to the driving block 321c by the second rotational coupler 323c may move in the direction away from the power source 321a by the driving block 321c while rotating. In this case, the transfer block 322a may be coupled to the link block 323 by the first rotational coupler 323b, the transfer block 322a may move in a direction toward the ball screw 321b while rotating such as the second rotational coupler 323c. Therefore, the transfer block 322a may be moved in the direction toward the ball screw 321b in the first direction x. In this case, the transfer blocks 322a may be located symmetrically with respect to the ball screw 321b, the pair of transfer blocks 322a may move closer to each other toward the ball screw 321b.

Conversely, when the driving block 321c moves toward the power source 321a, the pair of transfer blocks 322a may move in the first direction x so as to move away from each other from the ball screw 321b through the above-described process.

According to example embodiments, the first and the second rotational couplers 323b and 323c may rotate by the veering B such that each of the first and the second rotational couplers 323b and 323c may rotate with the uniformly accelerated linear movement. Therefore, the transfer block 322a may move with the uniformly accelerated linear movement so that the gripper 330 coupled to the transfer block 322a may also operate with the uniformly accelerated linear movement. As a result, the efficiency of the gripping operation of the gripper module 300 may be considerably improved. Further, it may be prevented or removed a failure of gripping operation caused by the abrasion between the cam housing and the cam follower due to the structural characteristics of the cam follower. In the conventional gripper module, when the cam follower moves by the link block in the cam housing having a curved face, the abrasions of the cam follower and the cam housing must be occurred and the precision of the gripping operation of the gripper module decreases as the operation time of the gripper module increases. However, according to example embodiments, the failure of the gripping operation of the gripper module 300 may be prevented or removed by using the bearing B instead of the cam follower.

In example embodiments, the gripper 330 may pass through the base plate 310 and may be coupled to the transfer block 322a. The gripper 330 may move between a gripping position P1 and a release position P2 according to the linear movement of the transfer block 322a. The carrier 10 may be gripped by the gripper 330 at the gripping position P1 and the carrier 10 may be separated from the gripper 330 at the release position P2.

The gripper 330 may include a pair of upper blocks 331 and a lower block 332. The pair of upper blocks 331 may be coupled to end portions of the pair of gripper coupling plates 322c extending under the base plate 310, respectively. The upper blocks 331 may extend in the second direction y to face each other while being spaced apart from each other by a reception space RS for receiving the carrier 10. The lower block 332 may have a line shape extending in the second direction y. The lower block 332 may be coupled to a rear surface of the upper block 331 to cover the reception space RS so as to provide the reception space RS as a reception groove G for receiving the flange of the carrier 10.

The gripper coupling plate 322c may be coupled to the both end portions of the transfer block 322a and may be downwardly extended by passing through a through line PL provided on the base plate 310. The through line PL may extend in the first direction x and may have a length longer than a width of the gripper coupling plate 322c.

The gripper coupling plate 322c may be coupled to the both end portions of the transfer block 322a by a fixing device P and may pass through the through line PL. The gripper coupling plate 322c may move in the same direction as the transfer block 322a while passing through the through line PL when the transfer block 322a is moved by the driving force transmitted by the driving block 321c and the link block 323.

The gripper 330 may be fixed to the gripper coupling plate 322c by the fixing device P such that the gripper 330 may also move by the movement of the gripper coupling plate 322c. When the driving block 321c moves away from the power source 321a, the pair of transfer blocks 322a may move closer to each other in the first direction x. Further, the pair of gripper coupling plates 322c coupled to the pair of transfer blocks 322a, respectively, may be placed at end portions of the through line PL adjacent the driving part 310.

The grippers 330 fixed to the pair of gripper coupling plates 322c respectively, may be arranged closest to each other in the first direction (x) and may be positioned in the gripping position P1 at which the carrier 10 is gripped. The end portion of the through line PL may serve as a first positioning guide for placing the gripper coupling plate 322c in the gripping position P1.

Conversely, when the driving block 321c moves closer to the power source 321a, the pair of transfer blocks 322a may move away from each other in the first direction x and the pair of gripper coupling plates 322c coupled to the pair of transfer blocks 322a respectively, may be positioned at end portions of the through line PL spaced apart from the driving part 321. In this case, the grippers 330 fixed to the pair of gripper coupling plates 322c respectively, may be disposed farthest from each other in the first direction x and the grippers 330 may be arranged at the release position P2. The end portion of the through line PL may serve as a second positioning guide for placing the gripper coupling plate 322c in the release position P2.

The pair of grippers 330 may be closest to each other at the gripping position P1 and each flange 11 disposed on an upper portion of the carrier 10 as illustrated in FIG. 2 may be received in the reception groove G provided in each of the grippers 330. Therefore, the carrier 10 may be gripped and held by the pair of grippers 330.

The gripper module 300 having the above described configuration may be disposed over the transfer vehicle 100 and may selectively perform the gripping operation and the release operation about the carrier 10 in accordance with the transfer algorithm for the carrier 10. Particularly, the link block 323, the driving part 321 and the gripper transfer part 322 may be rotatably combined using the bearing B such that the gripper module 300 may perform the gripping operation on the carrier 10 with the uniformly accelerated linear motion.

Hereinafter, the method of gripping the carrier 10 using the gripper module 300 will be described with reference to the accompanying drawings.

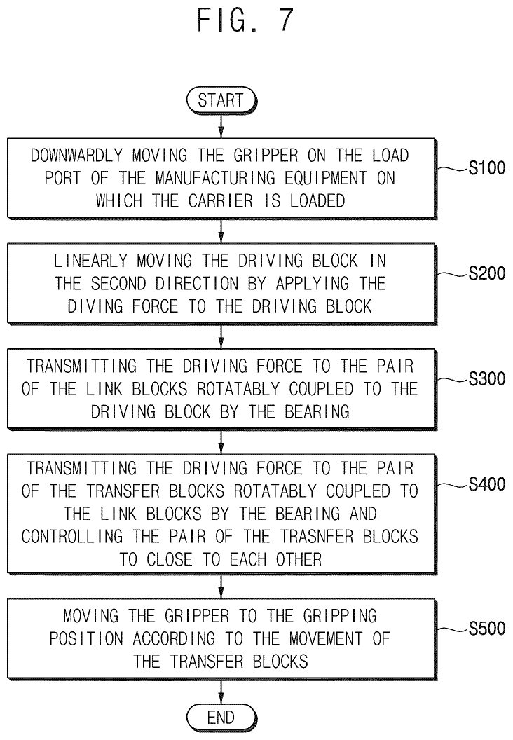

FIG. 7 is a flow chart illustrating a method of gripping a carrier using a substrate transfer apparatus in accordance with example embodiments of the invention.

Referring to FIG. 7, in step S100, the gripper 330 is downwardly moved on the load port of the manufacturing equipment according to the transfer algorithm.

The substrate transfer apparatus 500 may be moved to the load port of the manufacturing equipment on which the carrier 10 having the substrates is loaded according to the sequences in the semiconductor manufacturing line. The substrate transfer apparatus 500 may receive the position information of the manufacturing equipment from the control center in the semiconductor manufacturing line. The substrate transfer apparatus 500 may control the transfer vehicle 100 such that the transfer vehicle 100 including the gripper module 300 therein may be placed on the load port of the manufacturing equipment.

The gripper coupling plate 322c may be downwardly moved and the pair of the grippers 330 located under the end portions of the base plate 310 may be descended along the first direction x. Thus, the carrier 10 may be placed between the pair of the grippers 330.

In step S200, the driving block 321c may be linearly moved in the second direction away from the power source 321a using the driving force.

The power source 321a may be connected to the driving block 321c by the ball screw 321b so that the driving block 321c may linearly move away from the power source 321a or toward the power source 321a.

The driving part 321 may move the gripper 330 to the gripping position P1 when the driving block 321c is away from the power source 321a. However, the invention may not be limited thereto and the gripper 330 may be moved to the gripping position P1 when the driving block 321c is closed to the power source 321a.

In step S300, the driving force may be transmitted to the pair of the line blocks blocks 323a rotatably coupled to the driving block 321c by the bearing B.

The driving block 321c and the link block 323a may be rotatably coupled by the second rotational coupler 323c including the bearing B so that the driving force may be transmitted to the link block 323a. In this case, the link block 323a may rotate by the bearing B, and thus the link block 323a may rotate with the uniform accelerated motion.

In step S400, the driving force may be transmitted to the pair of the transfer blocks 322a rotatably coupled to the link blocks 323c by the bearing B and the pair of the transfer blocks 322a may be controlled to close to each other.

The link block 323a and the transfer block 322a may be rotatably coupled by the first rotational coupler 323b including the bearing B so that the driving force may be transmitted to the transfer block 322a. In this case, the transfer block 322a may rotate by the bearing B, and thus the transfer block 322a may rotate with the uniform accelerated motion.

In step S500, the gripper 330 may be moved to the gripping position P1 according to the movement of the transfer block 322a.

The gripper 330 may be coupled to the transfer block 322a by the gripper coupling plates 322c coupled to the end portions of the transfer block 322a so that the gripper 330 may be placed in the gripping position P1 according to the movement of the transfer block 322a. In this case, the transfer block 322a may move with the uniform accelerated linearly movement so that the gripper 330 may also move to the gripping position P1 with the uniform accelerated linearly movement. Therefore, the efficiency of the gripping operation of the gripper 330 may be improved.

According to the substrate transfer apparatus 500 including the gripper module 300, the gripper module 300 may be disposed on the upper portion of the transfer vehicle 100 and the gripper module 300 may selectively perform the gripping operation and the release operation about the carrier 10 according to the transfer algorithm of the carrier 10. Particularly, the link block 323, the driving part 321 and the gripper transfer part 322 may be rotatably coupled by the bearing B such that the gripper module 300 may perform the gripping operation on the carrier 10 with the uniform accelerated linearly movement. Further, the failure of gripping operation caused by the conventional cam follower may be prevented or removed so that the decrease in the efficiency of the substrate transfer apparatus 500 may be prevented.

The foregoing is illustrative of embodiments and is not to be construed as limiting thereof. Although a few embodiments have been described, those skilled in the art will readily appreciate that many modifications are possible in the embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A gripper module comprising:
a base plate having a length in a first direction and a width in a second direction substantially perpendicular to the first direction;
a driving part including a power source configured to generate a driving force, and a driving block linearly configured to move in the second direction by the driving force and to extend in the first direction;
a gripper transfer part including a transfer block configured to be separated from an end portion of the driving block, to extend in the second direction and to linearly move in the first direction;
a link block configured to be coupled to the driving block and the transfer block, and to convert a linear movement of the driving block in the second direction into a uniform accelerated linear movement of the transfer block in the first direction; and
a gripper configured to be rotatably coupled to the line block, to move a gripping position and a release position according to the uniform accelerated linear movement of the transfer block, and to grip a carrier in the gripping position.

2. The gripper module of claim 1, wherein the link block comprises:
a body having a bar shape;
a first rotational coupler configured to pass through a first end portion of the body, to include a bearing disposed in a first through hole having a body step, and to rotatably couple the transfer block to the body; and
a second rotational coupler configured to pass through a second end portion of the body, to include a bearing disposed in a second through hole having a body step, and to rotatably couple the driving block to the body.

3. The gripper module of claim 2, wherein the first rotational coupler comprises:
a coupling base including a lower base configured to be fixed to the transfer block, and an upper base configured to extend from the lower base toward a central portion of the first through hole and to be surrounded by the bearing; and
a fixing part configured to fill the first through hole, to separate the bearing from an outside and to fix the bearing to the upper base.

4. The gripper module of claim 3, wherein the upper base includes an outer surface having a surface step corresponding to the body step and the upper base is configured to provide a space for receiving the bearing over the body step and the surface step.

5. The gripper module of claim 4, wherein the bearing comprising:
a turning wheel configured to disposed on both of the body step and the surface step, to surround the upper base and to rotate relative to the upper base;
a retainer configured to disposed over the turning wheel and to surround the upper base; and
a plurality of rigid body balls configured to arrange in the retainer by a constant distance and to rotate along a circumference of the upper base according to a rotation of the body.

6. The gripper module of claim 2, wherein the gripper transfer part comprises:
a transfer bracket configured to be coupled to a central portion of the transfer block and to transfer the transfer block;
a transfer rail configured to be coupled to the transfer bracket, to extend in the first direction and to locate on the base plate; and
a pair of gripper coupling plates configured to be coupled to both end portions of the transfer block and to extent in a third direction perpendicular to the first direction and the second direction through the base plate.

7. The gripper module of claim 6, wherein the base plate comprising:
a first positioning guide configured to define a through line extending in the first direction through which the gripper coupling plates pass, and to place the gripper coupling plates in the gripping position adjacent to the driving part; and
a second positioning guide configured to place the gripper coupling plates in the release position separated from the driving part.

8. The gripper module of claim 6, wherein a pair of gripper transfer parts are provided on the base plate and separate from end portions of the driving block by a same distance, and wherein the pair of gripper transfer parts are coupled to the end portions of the driving part, respectively, by a pair of link blocks.

9. The gripper module of claim 6, wherein the gripper comprises:
a pair of upper blocks configured to be coupled to end portions of the pair of gripper coupling plates extending under the base plate 310, respectively. and to extend in the second direction to face each other while being spaced apart from each other by a reception space for receiving the carrier; and
a lower block configured to have a line shape extending in the second direction, to be coupled to a rear surface of the upper block to cover the reception space so as to provide the reception space as a reception groove for receiving a flange of the carrier.

10. The gripper module of claim 9, wherein a pair of grippers are disposed under the base plate to correspond to a pair of gripper transfer parts spaced apart by a same distance from the end portions of the driving block, and wherein the pair of grippers grip the carrier at the gripping position adjacent to the driving part and symmetrical to the driving part, and the pair of grippers are separated from the carrier in the release position separated from the driving part and symmetrical to the driving part.

11. A substrate transfer apparatus comprising:
a transfer vehicle configured to grip a carrier including a plurality of substrates and to transfer the carrier;
a traveling module configured to be disposed on an upper portion of the transfer vehicle and to transfer the transfer vehicle along a traveling rail connected to manufacturing equipments; and
a gripper module configured to be disposed in the transfer vehicle, to grip the carrier and to be fixed in the transfer vehicle, wherein the gripper module comprises:
a base plate having a length in a first direction and a width in a second direction substantially perpendicular to the first direction;
a driving part including a power source configured to generate a driving force, and a driving block linearly configured to move in the second direction by the driving force and to extend in the first direction;
a gripper transfer part including a transfer block configured to be separated from an end portion of the driving block, to extend in the second direction and to linearly move in the first direction;
a link block configured to be coupled to the driving block and the transfer block, and to convert a linear movement of the driving block in the second direction into a uniform accelerated linear movement of the transfer block in the first direction; and
a gripper configured to be rotatably coupled to the line block, to move a gripping position and a release position according to the uniform accelerated linear movement of the transfer block, and to grip a carrier in the gripping position.

12. The substrate transfer apparatus of claim 11, wherein the link block comprises:
a body having a bar shape;
a first rotational coupler configured to pass through a first end portion of the body, to include a bearing disposed in a first through hole having a body step, and to rotatably couple the transfer block to the body; and
a second rotational coupler configured to pass through a second end portion of the body, to include a bearing disposed in a second through hole having a body step, and to rotatably couple the driving block to the body.

13. The substrate transfer apparatus of claim 12, wherein the first rotational coupler comprises:
a coupling base including a lower base configured to be fixed to the transfer block, and an upper base configured to extend from the lower base toward a central portion of the first through hole and to be surrounded by the bearing; and
a fixing part configured to fill the first through hole, to separate the bearing from an outside and to fix the bearing to the upper base.

14. The substrate transfer apparatus of claim 13, wherein the upper base includes an outer surface having a surface step corresponding to the body step and the upper base is configured to provide a space for receiving the bearing over the body step and the surface step, and
wherein the bearing comprising:
a turning wheel configured to be disposed on both of the body step and the surface step, to surround the upper base and to rotate relative to the upper base;
a retainer configured to be disposed over the turning wheel and to surround the upper base; and
a plurality of rigid body balls configured to arrange in the retainer by a constant distance and to rotate along a circumference of the upper base according to a rotation of the body.

15. The substrate transfer apparatus of claim 11, wherein a pair of gripper transfer parts are provided on the base plate and separate from end portions of the driving block by a same distance, and wherein the pair of transfer part are coupled to the end portions of the driving part, respectively, by a pair of link blocks.

16. The substrate transfer apparatus of claim 15, wherein each of gripper transfer parts comprises:
a transfer bracket configured to be coupled to a central portion of the transfer block and to transfer the transfer block;
a transfer rail configured to be coupled to the transfer bracket, to extend in the first direction and to locate on the base plate; and
a pair of gripper coupling plates configured to be coupled to both end positions of the transfer block and to extent in a third direction perpendicular to the first direction and the second direction through the base plate.

17. The substrate transfer apparatus of claim 16, wherein the gripper comprises:
a pair of upper blocks configured to be coupled to end portions of the pair of gripper coupling plates extending under the base plate 310, respectively. and to extend in the second direction to face each other while being spaced apart from each other by a reception space for receiving the carrier; and
a lower block configured to have a line shape extending in the second direction, to be coupled to a rear surface of the upper block to cover the reception space so as to provide the reception space as a reception groove for receiving a flange of the carrier.

18. The substrate transfer apparatus of claim 17, wherein a pair of grippers are disposed under the base plate to correspond to a pair of gripper transfer parts spaced apart by a same distance from the end portions of the driving block, and wherein the pair of grippers grip the carrier at the gripping position adjacent to the driving part and symmetrical to the driving part, and the pair of grippers are separated from the carrier in the release position separated from the driving part and symmetrical to the driving part.

19. A method of gripping a carrier, which comprises:
downwardly moving a gripper onto a load port of a manufacturing equipment on which the carrier is loaded;
linearly moving a driving block in a second direction by using the diving force;
transmitting the driving force to a pair of the link blocks rotatably coupled to the driving block by a bearing;
transmitting the driving force to a pair of the transfer blocks rotatably coupled to the link blocks by the bearing and controlling the pair of the transfer blocks to close to each other; and
moving the gripper to a gripping position according to a movement of the transfer blocks.

20. The method of gripping a carrier of claim 19, wherein each of the transfer blocks and the gripper move with a uniform accelerated linear motion.
